(19) United States
(12) Patent Application Publication
(10) Pub. No.: US 2015/0206813 A1
(43) Pub. Date: Jul. 23, 2015

(54) METHODS AND STRUCTURES FOR PROCESSING SEMICONDUCTOR DEVICES

(71) Applicant: Micron Technology, Inc., Boise, ID (US)

(72) Inventor: Jaspreet S. Gandhi, Boise, ID (US)

(73) Assignee: Micron Technology, Inc., Boise, ID (US)

(21) Appl. No.: 14/162,537

(22) Filed: Jan. 23, 2014

(51) Int. Cl. H01L 23/06; H01L 23/18; H01L 25/00; H01L 23/498

(52) U.S. Cl. CPC H01L 23/06; H01L 23/498; H01L 23/18; H01L 25/50; H01L 2225/1017; H01L 2225/1041

(57) ABSTRACT

Methods of processing a semiconductor device include attaching a semiconductor substrate to a carrier substrate, forming a silane material over an exposed portion of the carrier substrate, and curing the silane material to form a hydrophobic coating over the carrier substrate. The hydrophobic coating may reduce or prevent undercut of the semiconductor substrate due to wicking of adhesive from between the semiconductor substrate and the carrier substrate during processing. The silane material includes a compound having a chemical formula of (XO)₃Si(CH₂)ₙY, (XO)₂Si((CH₂)ₙY)₂, or (XO)₃Si(CH₂)ₙY(CH₂)ₙSi(XO)₃, wherein XO is a hydrolyzable alkoxy group, Y is an organofunctional group, and n is a nonnegative integer. Some methods include forming a silane material over an exposed portion of a substrate, attaching a semiconductor device stack over the substrate, and forming an underfill material between substrates of the semiconductor device stack. Related structures are also disclosed.

### TECHNICAL FIELD

The present disclosure, in various embodiments, relates generally to compositions including a silane material and related methods, such as for maintaining other materials (e.g., adhesives, underfill materials) in place using the silane material during processing of a semiconductor device.

### BACKGROUND

Semiconductor devices and structures thereof are typically produced on a wafer or other bulk semiconductor substrate, which may be referred to herein as a “device wafer.” The array is then “singulated” into individual semiconductor devices, which may also be characterized as “dies” or “dice” that are incorporated into a package for practical mechanical and electrical interfacing with higher level packaging, for example, for interconnection with a printed wiring board. Device packaging may be formed on or around the die while it is still part of the wafer. This practice, referred to in the art as wafer-level packaging, reduces overall packaging costs and enables reduction of device size, which may result in faster operation and reduced power demand in comparison to conventionally packaged devices.

Thinning device wafer substrates is commonly conducted in semiconductor device manufacture because thinning enables devices to be stacked more easily while meeting dimensional constraints and enhances heat dissipation. However, thinner substrates are more difficult to handle without damage to the substrate or to the integrated circuit components thereon. To alleviate some of the difficulties, device wafer substrates are commonly attached to larger and more-robust carrier wafers. After processing, the device wafer substrates may be removed from the carrier wafers.

Common carrier materials include silicon (e.g., a blank device wafer), soda-lime glass, borosilicate glass, sapphire, and various metals and ceramics, among others. The carrier wafers are commonly substantially sized to match a size of the device wafer, so that the bonded assembly can be handled in conventional processing tools. Adhesives, such as polymeric adhesives, can be used for temporary wafer bonding are conventionally applied by spin coating or spray coating from solution or laminating as dry-film tapes. Spin- and spray-applied adhesives are increasingly preferred because they form coatings with higher thickness uniformity than tapes can provide. Higher thickness uniformity translates into greater control over cross-wafer thickness uniformity after thinning. The polymeric adhesives also exhibit high bonding strength to the device wafer and the carrier wafer.

During bonding, temporary adhesive may wick out from between the device wafer and the carrier substrate, and form on the carrier substrate. The adhesive that has wicked out is typically cleaned by a so-called “edge clean” process. Such a process may result in an undercut in the temporary adhesive bonding the device wafer to the carrier substrate where the edge of the device wafer is unsupported. The undercut increases the risk of wafer damage during subsequent processing, such as chemical-mechanical polishing (CMP). Though optimization is ongoing to design more-precise edge cleaning processes to reduce undercut, the temporary adhesive also tends to also wick when exposed to high temperature processes, such as CVD processes. Wicking of adhesive is problematic for some high temperature processes (e.g., PVD) because the presence of the excess adhesive results in non-uniform plating or complete failure to plate desired portions of the device wafer.

Another problem that may occur in forming semiconductor devices relates to the placement of underfill material. An underfill fillet may be used to cover an interface between a logic die and a DRAM stack. The material of the underfill fillet may extend over a surface of the logic die. If the material of the underfill fillet extends too far from the DRAM stack, the underfill fillet may interfere with the attachment of a conformal lid over the DRAM stack, resulting in reduced heat transfer from the DRAM stack and logic die and thermal degradation of the semiconductor dice of the package, resulting in not meeting operating temperature as well as thermal budget requirements.

### BRIEF DESCRIPTION OF THE DRAWINGS

FIGS. 1 through 6 are simplified cross sections of a semiconductor structure at various stages of processing with a hydrophobic material according to an embodiment of the present disclosure;

FIGS. 7 through 11 are simplified cross-sectional views of another semiconductor structure at various stages of processing with a hydrophobic material according to an embodiment of the present disclosure;

FIGS. 12 through 16 are simplified cross-sectional views of a semiconductor structure including a conformal lid at various stages of processing with a hydrophobic material according to an embodiment of the present disclosure; and

FIGS. 17 through 21 are simplified cross-sectional views of another semiconductor structure including a conformal lid at various stages of processing with a hydrophobic material according to an embodiment of the present disclosure.

### DETAILED DESCRIPTION

In some embodiments disclosed herein, methods of processing a semiconductor device are described, as are semiconductor structures and compositions for use in semiconductor processing. Some methods include attaching a semiconductor substrate to a carrier substrate, forming a silane material on the carrier substrate, and stabilizing the silane material to form a hydrophobic coating on the carrier substrate. The hydrophobic coating may limit or prevent wicking of adhesive from between the semiconductor substrate and the carrier substrate during subsequent processing acts, and thus reduce or prevent undercut of the semiconductor substrate.

As used herein, the term “semiconductor substrate” means and includes a base material or construction upon which components, such as those of memory cells and peripheral circuitry, as well as logic, may be formed. The semiconductor substrate may be a substrate wholly of a semiconductor material, a base semiconductor material on a supporting structure, or a semiconductor substrate having one or more materials, structures, or regions formed thereon. The semiconductor substrate may be a conventional silicon substrate or other bulk substrate including a semiconductor material. As used herein, the term “bulk substrate” means and includes not only silicon wafers, but also silicon-on-insulator (“SOI”) substrates, such as silicon-on-sapphire (“SOS”) substrates or silicon-on-glass (“SOG”) substrates, epitaxial layers of silicon on a base semiconductor foundation, or other semiconductor or optoelectronic materials, such as silicon-germanium (Si₁₋ₓGeₓ, wherein x is, for example, a mole fraction between 0.2 and 0.8), germanium (Ge), gallium arsenide (GaAs), gallium nitride (GaN), or indium phosphide (InP), among others. Furthermore, when reference is made to a “semiconductor substrate” in the following description, previous process stages may have been utilized to form materials, regions, or junctions, as well as connective elements such as lines, plugs, and contacts, in the base semiconductor structure or foundation, such components comprising, in combination, integrated circuitry. Semiconductor substrates may also be, for example, a carrier wafer that does not have components formed therein.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (rotated 90 degrees, inverted, flipped, etc.) and the spatially relative descriptors used herein interpreted accordingly.

As used herein, reference to an element as being “on” or “over” another element means and includes the element being directly on top of, adjacent to, underneath, or in direct contact with the other element. It also includes the element being indirectly on top of, adjacent to, underneath, or near the other element, with other elements present therebetween. In contrast, when an element is referred to as being “directly on” another element, there are no intervening elements present.

As used herein, the terms “comprises,” “comprising,” “includes,” and/or “including” specify the presence of stated features, regions, integers, stages, operations, elements, materials, components, and/or groups, but do not preclude the presence or addition of one or more other features, regions, integers, stages, operations, elements, materials, components, and/or groups thereof.

As used herein, “and/or” includes any and all combinations of one or more of the associated listed items.

As used herein, the singular forms “a,” “an,” and “the” are intended to include the plural forms as well, unless the context clearly indicates otherwise.

Embodiments are described herein with reference to the illustrations. The illustrations presented herein are not meant to be actual views of any particular material, component, structure, device, or system, but are merely idealized representations that are employed to describe embodiments of the present disclosure. Variations from the shapes of the illustrations as a result, for example, of manufacturing techniques and/or tolerances, are to be expected. Thus, embodiments described herein are not to be construed as being limited to the particular shapes or regions as illustrated, but include deviations in shapes that result, for example, from manufacturing. For example, a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the present claims.

The following description provides specific details, such as material types and processing conditions, in order to provide a thorough description of embodiments of the disclosed compositions and methods. However, a person of ordinary skill in the art will understand that the embodiments of the present disclosure may be practiced without employing these specific details. Indeed, the embodiments of the compositions and methods may be practiced in conjunction with conventional semiconductor fabrication techniques.

Any fabrication processes described herein do not form a complete process flow for processing semiconductor devices. Preceding, intermediary, and final process stages are known to those of ordinary skill in the art. Accordingly, only the methods and semiconductor structures necessary to understand embodiments of the present devices and methods are described herein.

Unless the context indicates otherwise, the materials described herein may be formed by any conventional technique including, but not limited to, dip coating, spin coating, spray coating, blanket coating, chemical vapor deposition (“CVD”), plasma-enhanced CVD, atomic layer deposition (“ALD”), plasma-enhanced ALD, or physical vapor deposition (“PVD”), as well as other deposition techniques known in the art. Alternatively, the materials may be grown in situ, unless the context otherwise indicates. Depending on the specific material to be formed, the technique for applying, depositing, growing, or otherwise forming the material may be selected by a person of ordinary skill in the art.

Disclosed are methods of processing semiconductor devices. The methods include bonding a semiconductor substrate to a carrier substrate, providing a silane material over an exposed portion of the carrier substrate, and solidifying the silane material to form a hydrophobic coating over the carrier substrate. The silane material may include a compound having a chemical formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer.

Reference will now be made to the drawings, where like numerals refer to like components throughout. The drawings are not necessarily to scale.

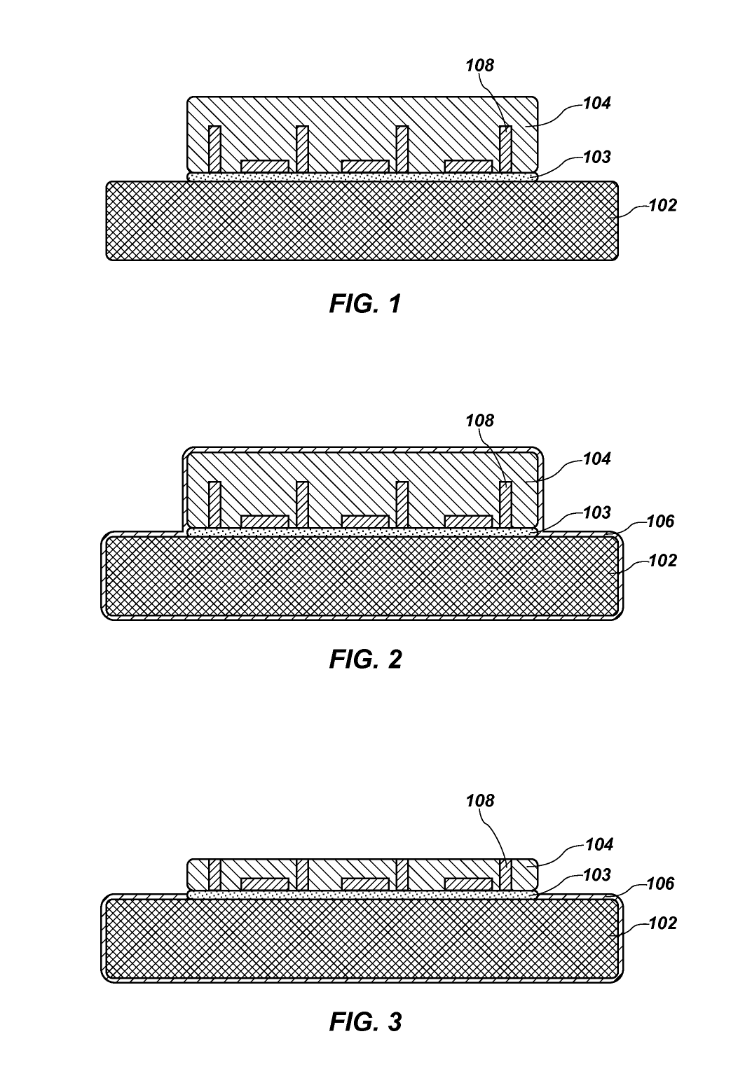

FIG. 1 illustrates a simplified cross section of a carrier substrate 102 over which a semiconductor substrate 104 is secured. The semiconductor substrate 104 may be a semiconductor material on which or in which conductive elements are to be formed, as described in further detail below. In some embodiments, the semiconductor substrate 104 may include circuit elements 108 (e.g., transistors, diodes, capacitors, resistors, bond pads, lines, traces, through-wafer interconnects, dielectric material, etc.). The semiconductor substrate 104 may be temporarily bonded to the carrier substrate 102 by an adhesive 103, as known in the art and not described in detail herein. The semiconductor substrate 104 may have a smaller diameter than the diameter of the carrier substrate 102 such that a portion of the surface of the carrier substrate 102 is free of the semiconductor substrate 104, such as around an edge of the semiconductor substrate 104.

As shown in FIG. 2, a hydrophobic coating 106 may be formed over at least a portion of the carrier substrate 102 and the semiconductor substrate 104. For example, the hydrophobic coating 106 may be formed over the entire exposed surfaces of the carrier substrate 102 and the semiconductor substrate 104. Since the hydrophobic coating 106 is hydrophobic, water may be repelled from the surface of the hydrophobic coating 106 over the carrier substrate 102 and/or the semiconductor substrate 104. In some embodiments, the hydrophobic coating 106 may exhibit a contact angle with water of greater than about 60°, greater than about 70°, or greater than about 80°. In some embodiments, the hydrophobic coating 106 may exhibit a contact angle with water from about 90° to about 100°. In other embodiments, the hydrophobic coating 106 may be superhydrophobic, exhibiting a contact angle with water greater than about 90° (e.g., about 125° or greater). As a point of reference, hydrophilic (wettable) surfaces generally have contact angles with water of about 35° or less.

The hydrophobic coating 106 may be a material formed, for example, by exposing the carrier substrate 102 and the semiconductor substrate 104 to a coat-forming composition. One or more components of the coat-forming composition may be reactive with one or more components of the carrier substrate 102 and/or the semiconductor substrate 104.

The coat-forming composition may include, for example and without limitation, a silane material. As used herein, the terms “silane” and “silane material” mean and include a chemical compound including silicon and at least one other element, e.g., carbon, hydrogen, nitrogen, sulfur, or a combination thereof. The silane material may be formulated as a non-functional silane or as a functional silane.

As used herein, the term “non-functional silane” means a silane material having an alkoxy group formulated to react with a metal material (e.g., in the carrier substrate 102) but lacking a functional group reactive with a nonmetallic material. Non-functional silanes may have stable functional groups connected to a silicon atom, such as phenyl groups, tolyl groups, alkyl groups, pentafluorophenyl groups, etc. Thus, non-functional silanes form a coating over the carrier substrate 102 that is relatively inert during conventional processing operations. Examples of non-functional silane materials include, but are not limited to, silane compounds including the formula —Si—(OC₂H₅)ₓ, or —Si—(OCH₃)ₓ, wherein x is an integer, and including either a methoxy or an ethoxy group bonded to the Si atom. The methoxy or ethoxy group is hydrolyzable to form a silanol (i.e., a —Si—OH), and an alcohol (e.g., methanol or ethanol) may be formed as a by-product. Examples of such non-functional silanes include, without limitation, the materials listed and shown in Table 1, which table is not exhaustive.

TABLE 1
Examples of Non-functional Silanes and Chemical Structures

| Non-functional | |
|---|---|
| Silane | Chemical Structure |
| p-tolyltrimethoxy- silane | 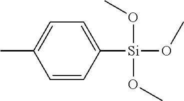 |
| p-tolyltriethoxy- silane | 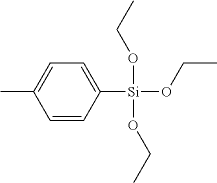 [SMILES: CCO[Si](OCC)(OCC)c1ccc(C)cc1] |
| di(p-tolyl)di- methoxysilane | 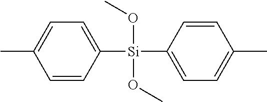 |
| pentafluorophenyl- triethoxysilane | 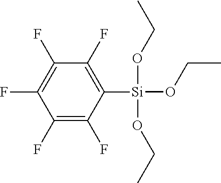 [SMILES: CCO[Si](OCC)(OCC)c1c(F)c(F)c(F)c(F)c1F] |
| 1,2-bis- [triethoxysilyl] ethane (BTSE) | 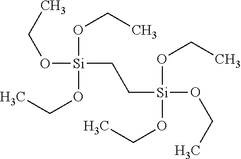 [SMILES: CCO[Si](CC[Si](OCC)(OCC)OCC)(OCC)OCC] |
| bis-trimethoxysilyl- ethylbenzene | 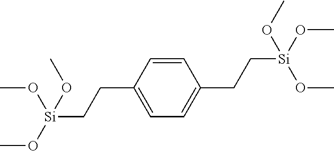 |
| bis-[trimethoxysilyl] octane (BTSO) | 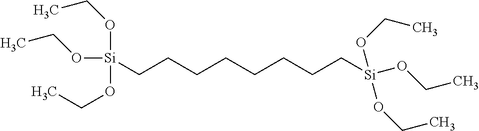 [SMILES: CCO[Si](CCCCCCCC[Si](OCC)(OCC)OCC)(OCC)OCC] |
| bis-[trimethoxysilyl] decane (BTSD) | 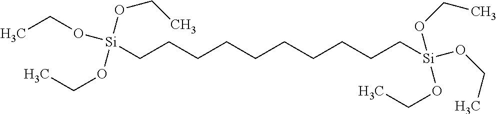 [SMILES: CCO[Si](CCCCCCCCCC[Si](OCC)(OCC)OCC)(OCC)OCC] |

As used herein, the term “functional silane” means a silane material formulated to react with the carrier substrate 102 and having a functional group reactive with a nonmetallic material of the carrier substrate 102. Functional silanes may have reactive functional groups directly or indirectly connected to a silicon atom, such as mercapto groups, sulfur groups, amine groups, epoxy groups, halogen groups, alkene groups, etc. Thus, functional silanes form a coating over the carrier substrate 102 that reacts during some conventional processing operations. For example, and without limitation, a functional silane material may be an organofunctional silane with one or more of the organofunctional groups or chemical structures in Table 2, which table is not exhaustive.

TABLE 2
Examples of Organofunctional Groups and Chemical Structures

| Organofunctional Group | Example Chemical Structure |
|---|---|
| Vinyl | H₂C═CHSi(OCH₃)₃ |
| Chloropropyl | Cl(CH₂)₃Si(OCH₃)₃ |
| Epoxy | 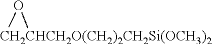 |
| Methacrylate | 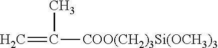 |
| Primary Amine | H₂N(CH₂)₃S1(OCH₃)₃ |
| Diamine | H₂N(CH₂)₂NH(CH₂)₃Si(OCH₃)₃ |
| Mercapto | HS(CH₂)₃Si(OCH₃)₃ |

Examples of functional and non-functional silanes include, but are not limited to, a hybrid organic-inorganic compound with the formula (XO)₃Si(CH₂)ₙY, (XO)₂Si((CH₂)ₙY)₂, or (XO)₃Si(CH₂)ₙY(CH₂)ₙSi(XO)₃, wherein XO represents a hydrolyzable alkoxy group (e.g., methoxy, ethoxy), n represents an integer, and Y represents an organofunctional group, such as, for example, and without limitation, an alkyl, tolyl, phenyl, amino, sulfur, carboxyl, or thiol group. The organofunctional group Y may include various substitutions, such as halogens, hydroxyl groups, etc. Whether such materials are functional or non-functional depends on the characteristics of the organofunctional group Y. For example, if the organofunctional group Y includes fluorine-terminated groups (e.g., pentafluorophenyltriethoxysilane, as shown in Table 1), the material may be non-functional because the fluorine does not tend to react with other materials.

When a silane material, either functional or non-functional, is hydrolyzed in water, or, alternatively, in an alcohol and water mixture, silanol groups (i.e., Si—OH groups) may form. The silanol groups of the hydrolyzed coat-forming composition may be reactive with hydroxyl groups, such as those on the surface of a metal material or other material that has been exposed to oxygen and moisture. That is, exposure of a metal material or other material to oxygen may form oxides on the surface of the metal material or other material. Subsequent exposure of the formed oxides to moisture may form M-OH bonds, wherein M represents a metal (for example, and without limitation, Cu, Ni, Sn, Al, Ag) or Si. Thus, metal or silicon components of the carrier substrate 102 may include hydroxyl bonds on their surfaces. Exposure of such hydroxyl bonds to silanol groups of a hydrolyzed silane material may lead to reaction, e.g., a condensation reaction, of the hydroxyl groups with the silanol groups, forming M-O—Si bonds, wherein M represents a metal, or Si—O—Si. Accordingly, exposure of the carrier substrate 102 and/or the semiconductor substrate 104 to a coat-forming composition including a silane material, water, and, optionally, an alcohol, may enable reaction between the coat-forming composition and the surface of the carrier substrate 102 and/or the semiconductor substrate 104 to form the hydrophobic coating 106 on the metallic component wherein the coating includes M-O—Si bonds (metal-oxygen-silicon bonds) or Si—O—Si bonds (silicon-oxygen-silicon bonds).

Both functional and non-functional silane materials may be formulated to react with the carrier substrate 102 and/or the semiconductor substrate 104, as described above. Functional silane materials may be formulated to be additionally reactive. For example, in embodiments in which the silane material of the coat-forming composition includes an alkoxy (e.g., methoxy, ethoxy, etc.) group, the alkoxy groups of the silane material are hydrolyzable to form silanols that may react with the hydroxyl groups of the carrier substrate 102 and/or the semiconductor substrate 104. For example, and without limitation, the alkoxy groups of the silane material in the coat-forming composition may be hydrolyzed to silanols as illustrated in [symbol] the following example reactions:

R′Si(OR)₃+H₂O [symbol] R′Si(OR)₂OH+ROH

R′Si(OR)₂OH+H₂O [symbol] R′Si(OR)(OH)₂+ROH

R′Si(OR)(OH)₂+H₂O [symbol] R′Si(OH)₃+ROH.

wherein R′ and R represent hydrocarbons. The silanols may then react with the hydroxides of the carrier substrate 102 and/or the semiconductor substrate 104 to form M-O—Si bonds or Si—O—Si bonds and water as illustrated in the following reaction, wherein the dashed line illustrates a surface of the carrier substrate 102 and/or the semiconductor substrate 104:

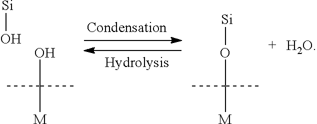

Examples of such alkoxy-including functional silane materials include, but are not limited to, monosilanes such as y-aminopropyltriethyoxysilanes (y-APS), y-methacryloxypropyltriethoxysilanes (y-MPS), or y-glycidoxypropyltrimethoxysilanes (y-GPS), and bis-silanes such as bis-[trimethoxysilylpropyl]amine (available under the name SILQUEST® A-1170 Silane from Momentive Performance Materials, Inc., of Columbus, Ohio), or bis[3-triethoxysilylpropyl]tetrasulfide (available under the name SILQUEST® A-1289 Silane from Momentive Performance Materials, Inc.).

The silane material of the coat-forming composition may alternatively or additionally be formulated to include other functional groups. For example, and without limitation, a functional silane material including sulfur functional groups may react with metal within the carrier substrate 102 and/or the semiconductor substrate 104, forming M-S bonds, also referred to herein as “metal-sulfur bonds.” For example, a sulfur group of a sulfur-based functional silane material may react with copper within the carrier substrate 102 and/or the semiconductor substrate 104 to form Cu—S bonds (“copper-sulfur bonds”). Therefore, such hydrophobic coating 106 formed may include M-S bonds.

Silanol groups of a silane material, whether functional or non-functional, may also condense with one another during formation of the hydrophobic coating 106, forming Si—O—Si bonds. The formation of the Si—O—Si bonds may increase the density and the viscosity of the coating material as the hydrophobic coating 106 forms. Therefore, the formed hydrophobic coating 106 may include Si—O—Si bonds.

The hydrophobic coating 106 may be formed by exposing surfaces of one or more materials of the carrier substrate 102 and/or the semiconductor substrate 104 to the coat-forming composition. The surfaces of the carrier substrate 102 and/or the semiconductor substrate 104 may be exposed to a solution that includes the coat-forming composition, and the surfaces of the carrier substrate 102 and/or the semiconductor substrate 104 may be dip-coated, spin-coated, spray-coated, or otherwise covered with the coat-forming composition.

Such a solution may include the coat-forming composition, a solvent, and, optionally, water. The solvent used in the solution may include a water-based solvent, a solvent miscible in water, and/or an organic solvent. For example, an organic solvent such as an alcohol (e.g., methanol, ethanol), in which the coat-forming composition is miscible, may be used to form the solution.

The solvent used in the solution may be selected such that the solution is formulated to reduce or prevent gelling of the coat-forming composition within the solution. As used herein, the term “gelling” means and includes thickening of the solution, increasing viscosity of the solution, and/or decreasing flowability of the solution prior to exposure of the carrier substrate 102 and/or the semiconductor substrate 104 to the solution. For example, use of an alcohol as the solvent may prevent gelling of the silane material and maintain flowability of the solution during application thereof on the carrier substrate 102 and/or the semiconductor substrate 104.

In some embodiments, the coat-forming composition may further include water (e.g., deionized water) to facilitate hydrolysis of the silane material to form the aforementioned reactive silanols. Water in the solution may also facilitate formation of oxide and hydroxyl groups on the carrier substrate 102 and/or the semiconductor substrate 104 when the carrier substrate 102 and/or the semiconductor substrate 104 are exposed to the solution. In other embodiments, the solution may be formed by mixing the coat-forming composition with the solvent in the absence of water. Water may then be introduced to the solution before the solution is applied to the surfaces of the carrier substrate 102 and/or the semiconductor substrate 104. In still other embodiments, the surfaces of the carrier substrate 102 and/or the semiconductor substrate 104 may be first exposed to water and then exposed to the other components (e.g., coat-forming composition and solvent) of the solution.

The solution may be formed by adding the coat-forming composition including the silane material to the solvent (e.g., alcohol), and then adding water (e.g., deionized water). During and following addition of the components to the solution, the solution may be stirred to inhibit gelling of the silane material.

The solution may be formulated to exhibit a pH in the range of from about 3 to about 10, such as from about 4 to about 9 prior to application of the solution on the carrier substrate 102 and/or the semiconductor substrate 104. Such pH ranges may reduce or prevent gelling of the coat-forming composition (e.g., silane material). A solution with a pH lower than about 3 or a pH greater than about 10, on the other hand, may facilitate gelling of the silane material before exposure of the carrier substrate 102 and/or the semiconductor substrate 104 to the solution. In some embodiments, an acid or a base may be added to the solution to maintain the pH in a selected range. For example, acetic acid may be added to the solution.

The solution may include from about 1% by volume to about 20% by volume of the coat-forming composition including the silane material, based on the total volume of the solution. For example, and without limitation, the solution may include from about 5% by volume to about 10% by volume of the coat-forming composition, from about 80% by volume to about 90% by volume ethanol or other alcohol-based solvent, and from about 5% by volume to about 10% by volume deionized water.

The average thickness of the hydrophobic coating 106 may be dependent upon the concentration of the silane material in the solution used to form the hydrophobic coating 106. For example, a solution with a higher concentration of silane material, relative to a solvent and, if present, other components of the solution, may result in a thicker hydrophobic coating 106 compared to a solution with a lower concentration of silane material. However, solutions including high concentrations of silane material may have a higher propensity to gel than those with lower concentrations of silane material. Therefore, the concentration of the silane material in the solution used to form the hydrophobic coating 106 may be tailored to achieve a hydrophobic coating 106 of a selected average thickness without excessive gelling. For example, and without limitation, a solution including at least about 5% by volume silane material, at least about 5% by volume deionized water, and a remainder ethanol or other alcohol-based solvent may be used to produce a hydrophobic coating 106 with a thickness from about 250 nanometers to about 500 nanometers. As another example, a solution including about 2% by volume of silane material may be used to produce a hydrophobic coating 106 with an average thickness of about 80 nanometers to about 200 nanometers.

Application of a solution may be self-limiting such that one application of the solution covers the exposed surfaces of the carrier substrate 102 and/or the semiconductor substrate 104 to saturation. However, in some embodiments, multiple applications of the solution may be performed to form a thicker coating or to ensure the coating is continuous. Exposure of the carrier substrate 102 and/or the semiconductor substrate 104 to the solution may be accomplished within a time frame of from about 30 seconds to about 1 minute, or longer if desired.

The solution may optionally include another material formulated to interact with the silane material, such as to increase the solubility, reduce or prevent gelling, or increase the hydrophobicity of the resulting hydrophobic coating 106. For example, other materials that may be present in the solution include a tetraethylorthosilicate (TEOS) of the formula Si—(OC₂H₅)₄, colloidal alumina, etc.

After exposure of the carrier substrate 102 and/or the semiconductor substrate 104 to the coat-forming composition, either by way of direct exposure to the coat-forming composition or to a solution including the coat-forming composition, the coat-forming composition may be cured to stabilize the coat-forming composition. The curing conditions may depend on the silane material used as the coat-forming composition. For example, if the coat-forming composition includes a solvent, heating may cause evaporation of the solvent, leaving behind the hydrophobic coating 106. As another example, heating may cause a chemical reaction between components of the coat-forming composition or between a component of the coat-forming composition and the carrier substrate 102 and/or the semiconductor substrate 104. In some embodiments, the coating material may be cured at a temperature of at least about 100° C., at least about 125° C., or at least about 150° C. to form the hydrophobic coating 106. The cure temperature may be maintained for a period of time, such as for at least about ten (10) minutes, at least about thirty (30) minutes, or at least about one (1) hour. The cure time and temperature may be inversely related; to use a shorter cure time, a higher cure temperature may be used to achieve the same degree of cure. Curing the coat-forming composition may encourage reaction and bonding between the silane material and the carrier substrate 102 and/or the semiconductor substrate 104. The cure conditions may affect the properties of the hydrophobic coating 106, such as the density.

Thus, as shown in FIG. 2, a semiconductor device assembly may include a hydrophobic coating 106 including a silane material over the semiconductor substrate 104 and the carrier substrate 102. The silane material may comprise a compound having a structure selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer.

A portion of the hydrophobic coating 106 may be removed from the semiconductor substrate 104 and/or the carrier substrate 102. For example, as shown in FIG. 3, the portion of the hydrophobic coating 106 overlying an upper surface of the semiconductor substrate 104 may be removed, such as during subsequent processing of the semiconductor substrate 104. For example, the portion of the hydrophobic coating 106 may be removed during wafer thinning or backside reveal. In some embodiments, a portion of the hydrophobic coating 106 may be removed by chemical-mechanical polishing (CMP), among other processes. The hydrophobic coating 106 remaining may provide an area of the carrier substrate 102 over which the adhesive 103 does not generally wet or flow. For example, the hydrophobic coating 106 may limit or prevent the adhesive 103 from wicking out from between the carrier substrate 102 (e.g., due to processing at temperatures at which the adhesive 103 melts) and the semiconductor substrate 104.

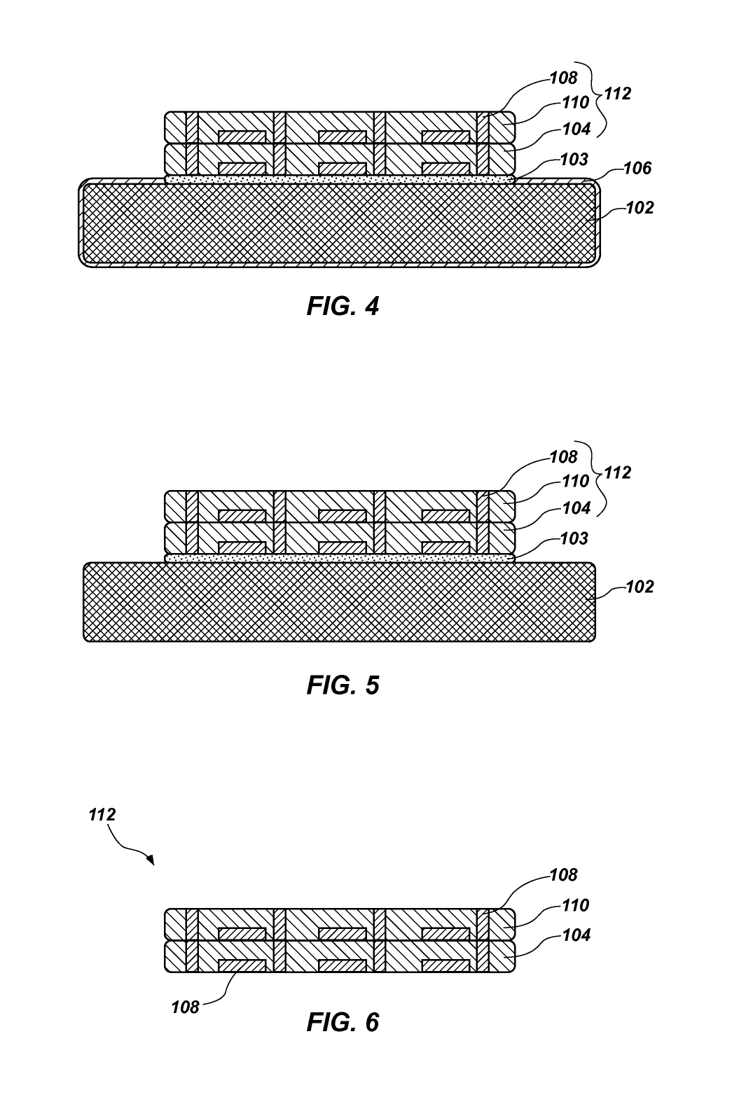

In subsequent processing operations, additional semiconductor substrates 110 and/or additional circuit elements 108, such as transistors, diodes, capacitors, resistors, bond pads, lines, traces, through-wafer interconnects, dielectric material, etc., may be formed. For example, as shown in FIG. 4, a semiconductor substrate 110 having various circuit elements 108 may be formed on or over the semiconductor substrate 104 by conventional techniques, which are not described in detail herein. Some of the processes for forming or securing the circuit elements 108 or semiconductor substrates 110 are high temperature processes, which would cause wicking of the adhesive 103 during a conventional process. However, the presence of the hydrophobic coating 106 in the semiconductor structure of the present disclosure may reduce or prevent wicking of the adhesive 103 during these additional processes by preventing the adhesive 103 from flowing over the hydrophobic coating 106. Together, the semiconductor substrate 104, the circuit elements 108 and the semiconductor substrates 110 may be referred to as a semiconductor device 112.

As shown in FIG. 5, the hydrophobic coating 106 may be removed after processing of the semiconductor device 112. The hydrophobic coating 106 may be removed, for example, by exposing the hydrophobic coating 106 to a solvent formulated to dissolve the hydrophobic coating 106. For example, the portion of the hydrophobic coating 106 may be removed by exposure to isopropanol, ethanol, methanol, acetone, etc.

After removal of the hydrophobic coating 106, the semiconductor device 112 may be removed from the carrier substrate 102, as shown in FIG. 6. The separation of the semiconductor device 112 and the carrier substrate 102 may be achieved by conventional techniques, which are not described in detail herein. For example, the semiconductor device 112 may be attached to a film supported by a film frame (not shown). The semiconductor device 112 may be singulated into a number of semiconductor dice (not shown). The individual semiconductor dice may then be individually removed from the film and used in subsequent processing operations.

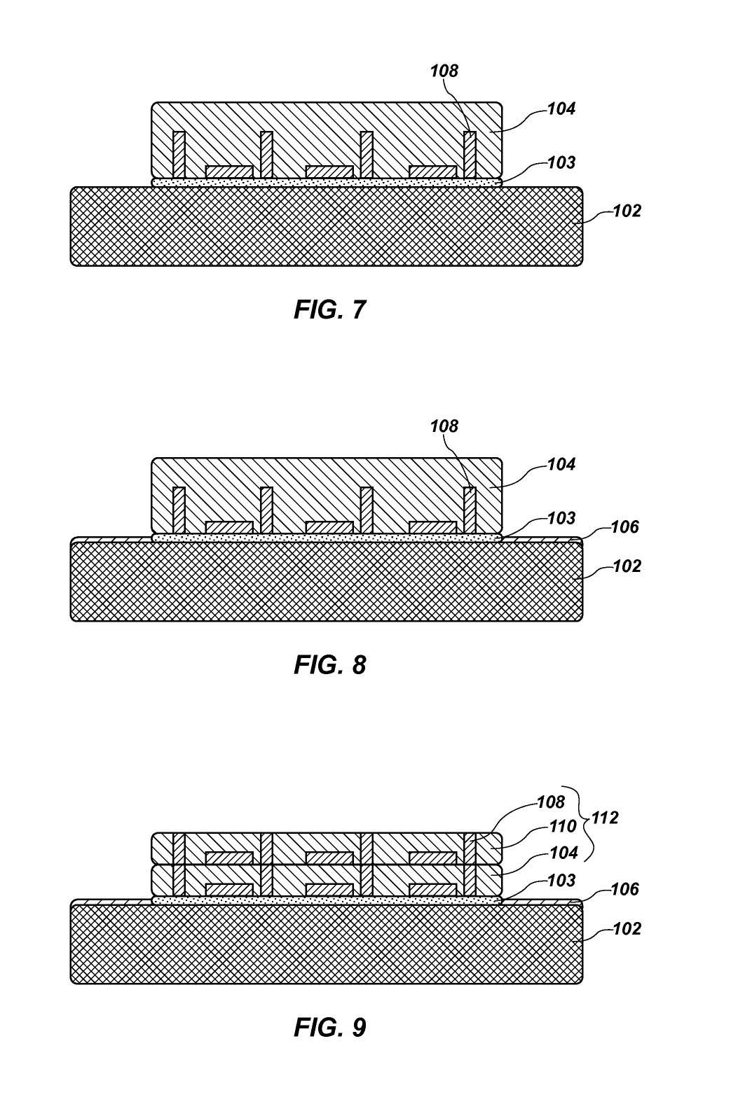

FIGS. 7 through 11 illustrate another method of processing semiconductor structures. The method depicted in FIGS. 7 through 11 differs from the method depicted in FIGS. 1 through 6 in that in the latter method, the hydrophobic coating 106 is provided over only a portion of the carrier substrate 102 peripherally around the semiconductor substrate 104, which may eliminate the need to remove a portion of the hydrophobic coating 106 before backside reveal or attaching additional semiconductor substrates 110.

FIG. 7 illustrates a simplified schematic of a carrier substrate 102 over which a semiconductor substrate 104 is secured. The semiconductor substrate 104 may be a semiconductor material in which circuit elements 108 have been formed. The semiconductor substrate 104 may be temporarily bonded to the carrier substrate 102 by an adhesive 103.

FIG. 8 illustrates a hydrophobic coating 106 formed over a portion of the carrier substrate 102 peripherally around the semiconductor substrate 104, such as exposed portions of the carrier substrate 102 surrounding the semiconductor substrate 104. The hydrophobic coating 106 may be a material as described above. The hydrophobic coating 106 may be applied as liquid coat-forming composition, which may be subsequently cured. The coat-forming composition may be applied via one or more nozzles, such as through a nozzle assembly of the type conventionally used for an edge-bead removal process. Such edge-bead removal processes are known in the art and are not described in detail herein.

As shown in FIG. 9, various processes may be performed on the semiconductor substrate 104, such as backside reveal. One or more additional semiconductor substrates 110 may be provided over the semiconductor substrate 104. Together, the semiconductor substrate 104, the circuit elements 108 and the semiconductor substrates 110 may be referred to as a semiconductor device 112.

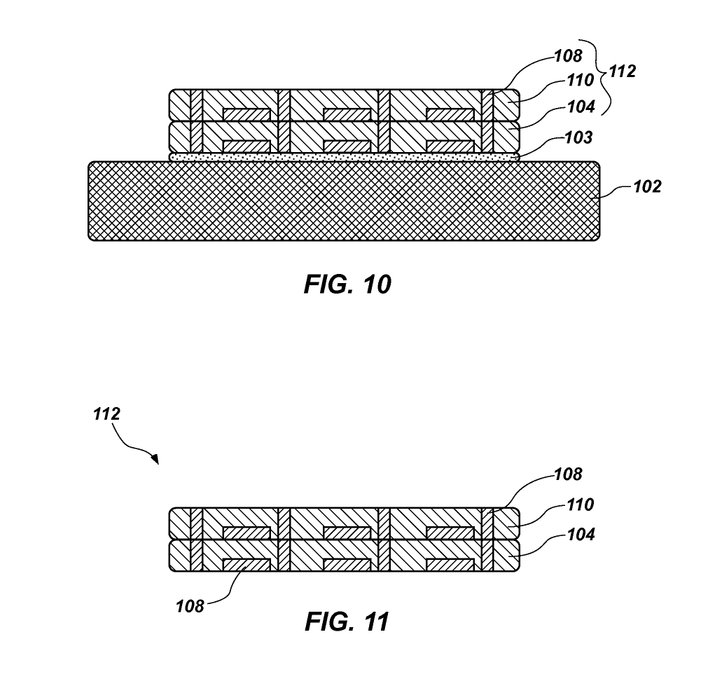

As shown in FIG. 10, the hydrophobic coating 106 may be removed after processing of the semiconductor device 112. The hydrophobic coating 106 may be removed, for example, by exposing the hydrophobic coating 106 to a solvent formulated to dissolve the hydrophobic coating 106. For example, the portion of the hydrophobic coating 106 may be removed by exposure to isopropanol, ethanol, methanol, acetone, etc.

After removal of the hydrophobic coating 106, the semiconductor device 112 may be removed from the carrier substrate 102, as shown in FIG. 11. For example, the semiconductor device 112 may be attached to a film supported by a film frame (not shown). The semiconductor device 112 may be singulated into a number of semiconductor dice (not shown). The individual semiconductor dice may then be individually removed from the film and used in subsequent processing operations.

The hydrophobic coating 106 described herein may reduce or prevent adhesive 103 from wicking out from between the carrier substrate 102 and the semiconductor substrate 104 during processing. For example, if the circuit elements 108 (e.g., transistors, diodes, capacitors, resistors, bond pads, lines, traces, through-wafer interconnects, dielectric material, etc.) are formed by high-temperature processes, such as CVD or PVD, the hydrophobic coating 106 may keep liquefied adhesive material in place between the carrier substrate 102 and the semiconductor substrate 104. The hydrophobic coating 106 may also provide physical support for the semiconductor substrate 104 during subsequent processing operations such as chemical-mechanical polishing (CMP). Films subsequently formed over the semiconductor substrate 104 may adhere more uniformly because the hydrophobic coating 106 may reduce or prevent flaking of the carrier substrate 102 and/or the semiconductor substrate 104. The hydrophobic coating 106 may also help the carrier substrate 102 and the semiconductor substrate 104 to maintain contact with one another during processing. At least for these reasons, semiconductor devices 112 formed as described may have a higher uniformity and a lower defect rate than semiconductor devices formed by conventional methods.

The present disclosure also describes methods of processing a semiconductor device that includes forming a silane material over an exposed portion of a substrate and attaching at least one semiconductor device stack over the substrate. The semiconductor device stack may comprise one or more (e.g., two, four, eight, etc.) semiconductor device substrates. A surface of the semiconductor device stack may be in physical and thermal contact with the substrate. An underfill material may be provided between the semiconductor device substrates, and the silane material may be removed from the semiconductor substrate. For example, the methods may be used to contain an underfill material within a selected area, and to maintain an area of a semiconductor structure free of the underfill material. Thus, a lid may be more reliably and securely attached over the semiconductor structure to the area free of underfill material. The methods may be performed on an entire wafer or at the die level.

In some embodiments disclosed herein, a method may include attaching a semiconductor device stack to a substrate, forming a silane material over an exposed portion of the substrate, curing the silane material to form a hydrophobic coating over the carrier substrate, and providing an underfill material between the semiconductor device substrates over the semiconductor substrate.

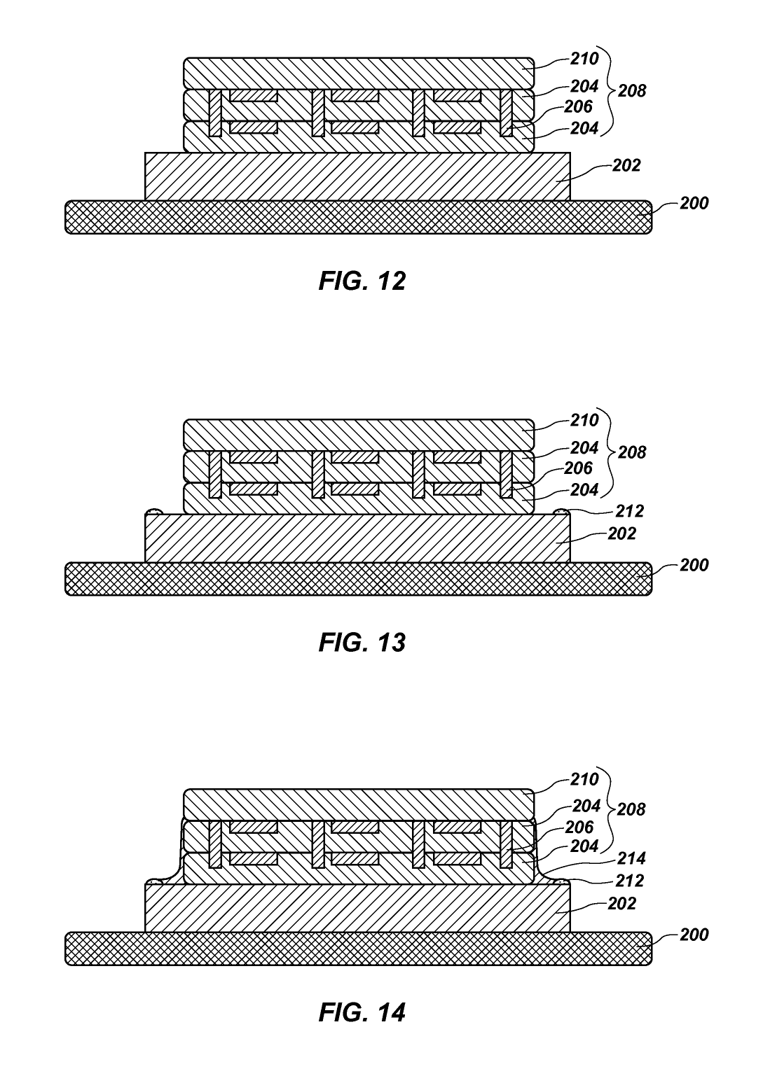

FIG. 12 is a simplified schematic cross section of a semiconductor structure during processing. The structure includes a logic die 202 secured to a substrate 200, such as by an adhesive (not shown). One or more semiconductor substrate(s) 204, 210 and circuit element(s) 206 may be formed over the logic die 202, and may together be referred to as a semiconductor device stack 208. For example, the semiconductor device stack 208 may be a DRAM stack.

A hydrophobic coating 212 may be provided over a portion of the logic die 202 such that a portion of the exposed surface of the logic die 202 remains exposed between the semiconductor device stack 208 and the hydrophobic coating 212. The hydrophobic coating 212 may be a silane material, as described above with respect to the hydrophobic coating 106 shown in FIGS. 2 through 4, 8, and 9.

An underfill material 214 may be provided between the semiconductor substrates 204, 210. As shown in FIG. 14, some of the underfill material 214 may cover at least a portion of the exposed surface of the logic die 202 between the semiconductor device stack 208 and the hydrophobic coating 212. Though not visible in FIG. 14, the underfill material 214 may be in a thin layer between the semiconductor substrates 204, 210. The underfill material 214 may be, for example, an electrical insulator, such as a polymer. The hydrophobic coating 212 may act as a barrier, keeping the underfill material 214 within a preselected area defined by the hydrophobic coating 212.

Thus, a semiconductor device assembly may include a first semiconductor substrate, a semiconductor stack comprising one or more additional semiconductor substrates over a portion of the first semiconductor substrate, and a silane material over a portion of the first semiconductor substrate. An underfill material may be adjacent the additional semiconductor substrates (e.g., between two substrates) and over the first semiconductor substrate and between the silane material and the semiconductor stack. The silane material may comprise a compound having a formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer.

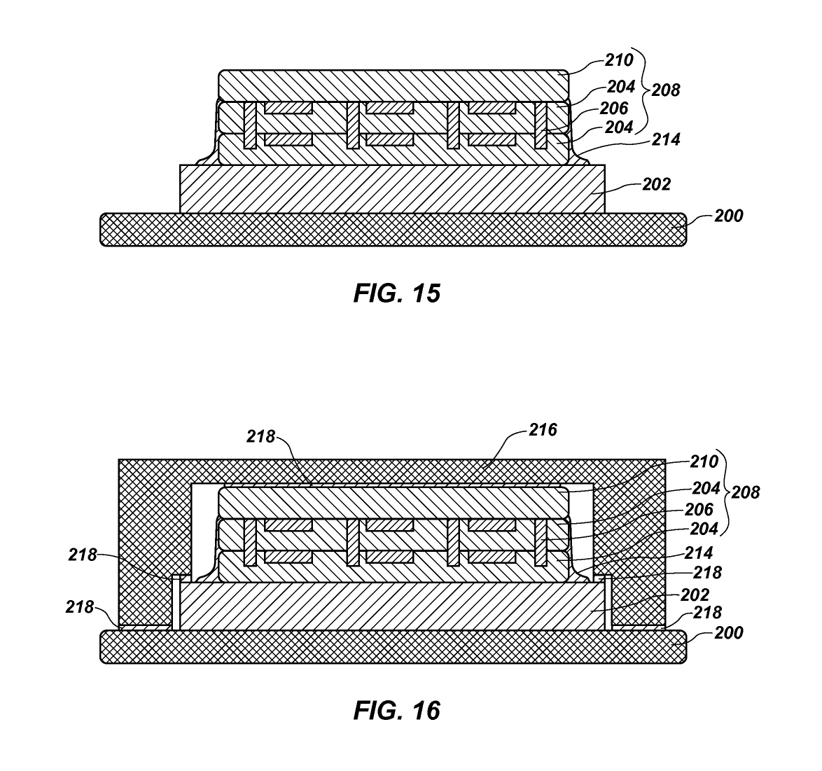

The hydrophobic coating 212 may be removed from the surface of the logic die 202, as shown in FIG. 15. The hydrophobic coating 212 may be removed by any conventional techniques, such as by sputtering with an argon plasma. The underfill material 214 may be recessed from the edge of the logic die 202, such that a conformal lid 216 may be placed over the semiconductor device stack 208 and over the logic die 202, as shown in FIG. 16. The conformal lid 216 may include, for example, a metal having a high thermal conductivity such that the conformal lid 216 acts as a heat sink to dissipate heat from the logic die 202 and the semiconductor device stack 208. The conformal lid 216 may include or be thermally connected to heat-dissipating features such as heat exchangers, heat sinks, heat pipes, or cooling plates. A thermal interface material 218 may be disposed between the semiconductor device stack 208 and the conformal lid 216 to further promote heat transfer from the semiconductor device stack 208 (e.g., from the semiconductor substrate 210) to the conformal lid 216. The thermal interface material 218 may also be disposed between the logic die 202 and the conformal lid 216 to promote heat transfer from the logic die 202. The thermal interface material 218 may also be disposed between the substrate 200 and the conformal lid 216 to promote heat transfer from the substrate 200. The thermal interface material 218 may be an electrical insulator, and may have a relatively high thermal conductivity with respect to the semiconductor substrate(s) 204, 210. The conformal lid 216 may abut the logic die 202, and may be held in place by a sealant (e.g., an adhesive).

In some embodiments disclosed herein, a method of forming a semiconductor device assembly includes forming a silane material on an exposed portion of a substrate, attaching a semiconductor device stack to the substrate, forming an underfill material between substrates of the semiconductor device stack, and removing the silane material from the substrate. The silane material comprises a compound having a chemical formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer. A surface of the semiconductor device stack may be in physical and thermal contact with the substrate.

FIGS. 17 through 21 illustrate another method in which a hydrophobic coating may be used to contain an underfill material. As shown in FIG. 17, a logic die 202 is secured to a substrate 200. A resist 220 may be formed over a portion of a surface of the logic die 202, and another portion of the logic die 202 may remain exposed. The resist 220 may cover the portion of the logic die 202 over which semiconductor substrate(s) may subsequently be secured.

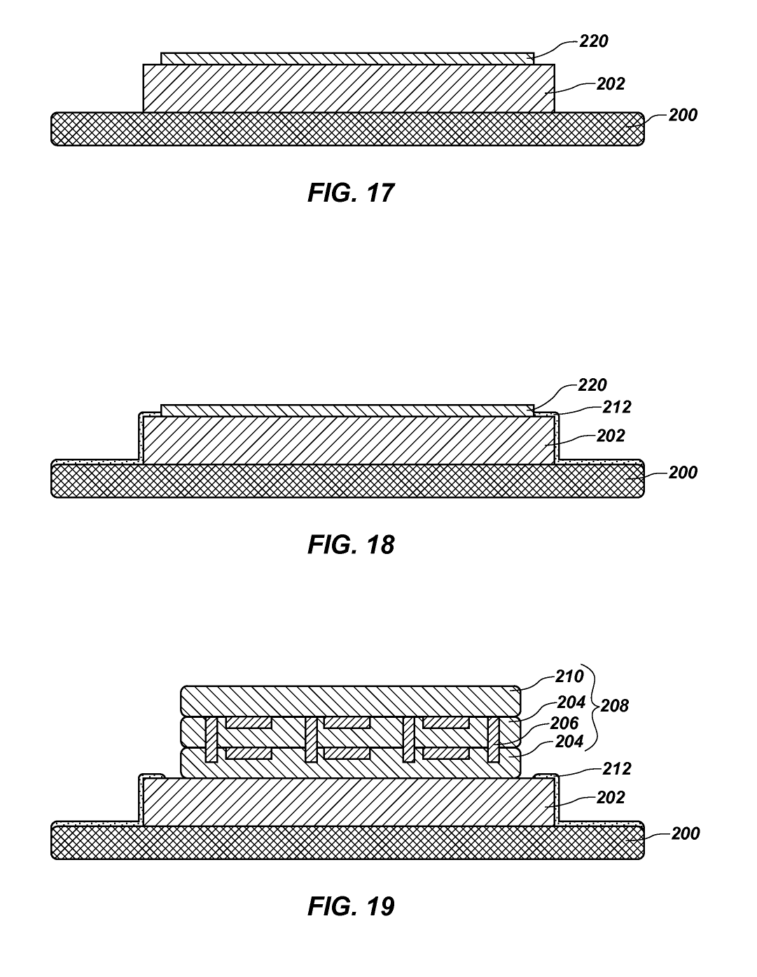

As shown in FIG. 18, a hydrophobic coating 212 may be provided over the exposed portion of the logic die 202 and/or the substrate 200. The hydrophobic coating 212 may be a silane material, as described above with respect to the hydrophobic coating 106 shown in FIGS. 2 through 4, 8, and 9.

As shown in FIG. 19, the resist 220 may be removed, and one or more semiconductor substrate(s) 204, 210 and circuit element(s) 206 may be formed over the logic die 202. The resist 220 may be removed by, for example, wet or dry etching. The semiconductor substrate(s) 204, 210 and circuit element(s) 206 may be provided over the logic die 202 as described above, and may together be referred to a semiconductor device stack 208. For example, the semiconductor device stack 208 may be a DRAM stack.

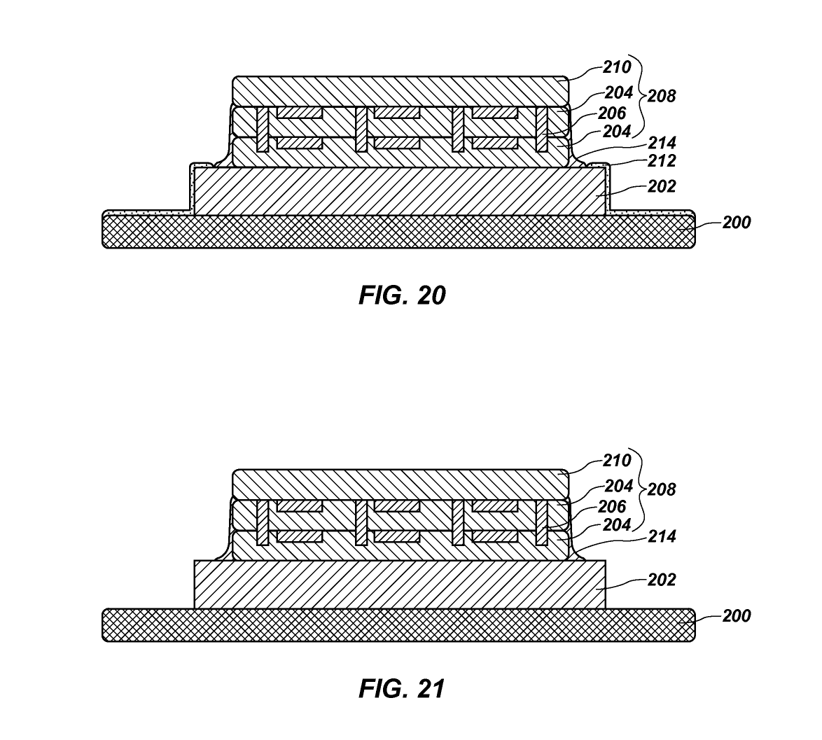

An underfill material 214 may be provided between the semiconductor substrates 204, 210. As shown in FIG. 20, some of the underfill material 214 may cover at least a portion of the exposed surface of the logic die 202 between the semiconductor device stack 208 and the hydrophobic coating 212. Thus, the hydrophobic coating 212 may act as a barrier, keeping the underfill material 214 within a preselected area defined by the hydrophobic coating 212. Though not visible in FIG. 20, the underfill material 214 may be in a thin layer between the semiconductor substrates 204, 210.

The hydrophobic coating 212 may then be removed from the surface of the logic die 202 and the substrate 200, as shown in FIG. 21. The underfill material 214 may be recessed from the edge of the logic die 202, such that a conformal lid 216 (see FIG. 16) may be placed over the semiconductor device stack 208 and over the logic die 202, as shown in FIG. 16 and described above. The hydrophobic coating 212 may be removed by any conventional techniques, such as by sputtering with an argon plasma.

The logic die 202 may, in some embodiments, be a wafer or a portion of a wafer sufficient to receive multiple semiconductor devices. In such embodiments, the logic die 202 may be singulated at any point during processing. For example the logic die 202 may be singulated after removal of the resist 220, and before providing the semiconductor device stack 208.

The hydrophobic coating 212 may function to contain the underfill material 214 within selected boundaries on the logic die 202. Thus, a surface of the logic die 202 may remain free of the underfill material 214 such that the conformal lid 216 may be properly attached. At least for these reasons, semiconductor devices formed as described may have a higher uniformity and a lower defect rate than semiconductor devices formed by conventional methods.

While the disclosed device structures and methods are susceptible to various modifications and alternative forms in implementation thereof, specific embodiments have been shown by way of example in the drawings and have been described in detail herein. However, it should be understood that the present disclosure is not intended to be limited to the particular forms disclosed. Rather, the present invention encompasses all modifications, combinations, equivalents, variations, and alternatives falling within the scope of the following appended claims and their legal equivalents.

What is claimed is:

1. A method of processing a semiconductor device, comprising:
attaching a semiconductor substrate to a carrier substrate;
forming a silane material on the carrier substrate, the silane material comprising a compound having a chemical formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer; and
stabilizing the silane material to form a hydrophobic coating on the carrier substrate.

2. The method of claim 1, wherein the hydrolyzable alkoxy group is selected from the group consisting of a methoxy group and an ethoxy group.

3. The method of claim 1, wherein Y comprises at least one aromatic ring.

4. The method of claim 1, wherein:
forming a silane material on the carrier substrate comprises forming the silane material over the semiconductor substrate and the carrier substrate; and
curing the silane material comprises forming the hydrophobic coating over the semiconductor substrate and the carrier substrate;
further comprising removing a portion of the hydrophobic coating from at least a portion of the semiconductor substrate.

5. The method of claim 4, wherein removing a portion of the hydrophobic coating from at least a portion of the semiconductor substrate comprises performing chemical-mechanical polishing on the semiconductor substrate.

6. The method of claim 1, wherein stabilizing the silane material comprises at least partially curing the silane material.

7. The method of claim 1, wherein the silane material comprises a material selected from the group consisting of 1,2-bis[triethoxysilyl]ethane, 1,2-bis[trimethoxysilyl]octane, and 1,2-bis[trimethoxysilyl]decane.

8. The method of claim 1, wherein forming a silane material on the carrier substrate comprises exposing the semiconductor substrate and the carrier substrate to a solution comprising the silane material.

9. The method of claim 8, wherein exposing the semiconductor substrate and the carrier substrate to a solution comprising the silane material comprises exposing the semiconductor substrate and the carrier substrate to a solution comprising the silane material and water.

10. The method of claim 8, wherein exposing the semiconductor substrate and the carrier substrate to a solution comprising the silane material comprises exposing the semiconductor substrate and the carrier substrate to a solution comprising the silane material and an organic solvent.

11. The method of claim 10, wherein exposing the semiconductor substrate and the carrier substrate to a solution comprising the silane material comprises exposing the semiconductor substrate and the carrier substrate to a solution comprising at least about five volume percent silane material, at least about five volume percent deionized water, and a remainder methanol or ethanol.

12. The method of claim 1, wherein forming a silane material on the carrier substrate comprises dispensing the silane material over an exposed portion of the carrier substrate while keeping the semiconductor substrate substantially free of the silane material.

13. The method of claim 1, wherein stabilizing the silane material comprises forming a polymeric material comprising at least one of Si—O—Si and M-O—Si over the carrier substrate, wherein Si is silicon, O is oxygen, and M is a metal.

14. The method of claim 1, wherein forming a silane material on the carrier substrate comprises exposing the at least a portion of the semiconductor substrate and the carrier substrate to a silane material selected from the group consisting of 1,2-bis[triethoxysilyl]ethane, 1,2-bis[trimethoxysilyl]octane, and 1,2-bis[trimethoxysilyl]decane.

15. A method of forming a semiconductor device assembly, comprising:
forming a silane material on an exposed portion of a substrate, the silane material comprising a compound having a chemical formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer;
attaching a semiconductor device stack to the substrate, the semiconductor device stack comprising one or more semiconductor device substrate, wherein a surface of the semiconductor device stack is in physical and thermal contact with the substrate;
providing an underfill material adjacent the one or more semiconductor device substrate; and
removing the silane material from the substrate.

16. The method of claim 15, further comprising curing the silane material on the exposed portion of the substrate.

17. The method of claim 15, further comprising attaching a conformal lid over the semiconductor device assembly.

18. The method of claim 15, wherein attaching a semiconductor device stack to the substrate comprises attaching at least one semiconductor device to a logic die.

19. The method of claim 15, wherein attaching a semiconductor device stack to the substrate comprises attaching a DRAM stack to the substrate.

20. The method of claim 15, wherein providing an underfill material adjacent the one or more semiconductor device substrate comprises providing an underfill material between two or more semiconductor device substrates.

21. A method of processing a semiconductor device, comprising:
attaching a semiconductor device stack to a substrate, the semiconductor device stack comprising at least two semiconductor substrates;
forming a silane material over an exposed portion of the substrate, the silane material comprising a compound having a chemical formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer;
curing the silane material to form a hydrophobic coating over the substrate; and
forming an underfill material between the at least two semiconductor substrates of the semiconductor device stack.

21. The method of claim 20, wherein forming a silane material over an exposed portion of the substrate comprises leaving a surface of the substrate exposed between the semiconductor device stack and the silane material.

22. The method of claim 20, further comprising removing the silane material from the substrate.

23. The method of claim 22, wherein removing the silane material from the substrate comprises exposing the silane material to an argon plasma.

24. The method of claim 20, further comprising providing a conformal lid over the semiconductor device stack.

26. The method of claim 25, further comprising providing a thermal interface material between the conformal lid and at least one of the semiconductor device stack and the substrate.

27. A method of processing a semiconductor device, comprising:
attaching a logic die to a substrate;
forming a resist over a portion of the logic die;
forming a silane material over an exposed portion of the substrate and an exposed portion of the logic die, the silane material comprising a compound having a chemical formula selected from the group consisting of (XO)₃Si(CH₂)ₙY, (XO)₂Si((CH₂)ₙY)₂, and (XO)₃Si(CH₂)ₙY(CH₂)ₙSi(XO)₃, wherein XO is a hydrolyzable alkoxy group, Y is an organofunctional group, and n is a nonnegative integer;
curing the silane material to form a hydrophobic coating over the exposed portion of the substrate and the exposed portion of the logic die;
attaching a semiconductor device stack over the logic die, the semiconductor device stack comprising one or more semiconductor substrates; and
forming an underfill material between the logic die and the one or more semiconductor substrates of the semiconductor device stack.
